(19) United States
(12) Patent Application Publication
(10) Pub. No.: US 2021/0025056 A1
(43) Pub. Date: Jan. 28, 2021

(54) ELECTROSTATIC CHUCK FOR DAMAGE-FREE SUBSTRATE PROCESSING

(71) Applicant: Applied Materials, Inc., Santa Clara, CA (US)

(72) Inventors: Prashant Kumar KULSHRESHTHA, San Jose, CA (US); Zheng John YE, Santa Clara, CA (US); Kwangduk Douglas LEE, Redwood City, CA (US); Dong Hyung LEE, Gyeonggi-do (KR); Vinay PRABHAKAR, Cupertino, CA (US); Juan Carlos ROCHA-ALVAREZ, San Carlos, CA (US); Xiaoquan MIN, Mountain View, CA (US)

(21) Appl. No.: 16/639,449

(22) PCT Filed: Oct. 8, 2018
(86) PCT No.: PCT/US2018/054860

§ 371 Date: Feb. 14, 2020

Related U.S. Application Data
(60) Provisional application No. 62/569,895, filed on Oct. 9, 2017.

(51) Int. Cl. C23C 16/458; H01J 37/32; C23C 16/50

(52) U.S. Cl. CPC C23C 16/4586; H01J 2237/3321; C23C 16/50; H01J 37/32715

(57) ABSTRACT

Embodiments of the disclosure relate to an improved electrostatic chuck for use in a processing chamber to fabricate semiconductor devices. In one embodiment, a processing chamber includes a chamber body having a processing volume defined therein and an electrostatic chuck disposed within the processing volume. The electrostatic chuck includes a support surface with a plurality of mesas located thereon, one or more electrodes disposed within the electrostatic chuck, and a seasoning layer deposited on the support surface over the plurality of mesas. The support surface is made from an aluminum containing material. The one or more electrodes are configured to form electrostatic charges to electrostatically secure a substrate to the support surface. The seasoning layer is configured to provide cushioning support to the substrate when the substrate is electrostatically secured to the support surface.

### BACKGROUND

### Field

Embodiments of the disclosure generally relate to a substrate support and a method of using the substrate support in semiconductor device manufacturing.

### Description of the Related Art

An electrostatic chuck is commonly used for holding a semiconductor substrate to a substrate support, for example, during deposition of a film layer on the substrate, etching of a film layer on the substrate, implanting ions into the substrate, and other processes. The electrostatic chuck chucks the substrate thereto by creating an attractive force between the substrate and the electrostatic chuck. A chucking voltage is applied to one or more electrodes in the electrostatic chuck to induce oppositely polarized charges in the substrate and the electrodes. The opposite charges pull the substrate and the electrostatic chuck together, thus fixing the substrate in place.

The growing demands of mobile computing and data centers continue to drive the need for higher-capacity, higher-performance NAND flash technology. With planar NAND technology nearing its practical scaling limits, NAND flash memory has moved from a planar configuration to a vertical configuration (V-NAND). In this vertical configuration, the memory devices are formed on the substrate at significantly greater memory cell densities. In the manufacturing of three-dimensional (3D) semiconductor chips, stair-like structures are often utilized to enable multiple interconnection structures to be formed, thus, enabling a high-density of vertical transistor devices.

One desire for these next generation devices is to achieve higher throughput as well as better device yield and performance from each processed memory device substrate. Future generations of NAND and DRAM devices will utilize a greater number of stacked oxide, nitride and/or polysilicide layers. Because these different materials are stacked one over the other, their different coefficients of thermal expansion can cause a substrate to warp or bow on the order of 300 um or more across a 300 mm substrate. Without sufficient clamping force to flatten bowed substrates during substrate processing, it becomes difficult to maintain a uniform temperature across the substrate and thus is difficult to achieve a uniform process result across the substrate. To chuck bowed substrates, a large chucking force is required. However, as a consequence of the large chucking force, the substrate can become damaged as a result of thermal expansion during and after chucking at locations of direct contact with the portions of the electrostatic chuck the substrate contacts.

Accordingly, there is a need for an improved electrostatic chuck for securing the substrate without backside damage during substrate processing.

### SUMMARY

In one embodiment, a processing chamber includes a chamber body having a processing volume defined within and an electrostatic chuck disposed within the processing volume. The electrostatic chuck comprises a support surface with a plurality of mesas located thereon and one or more electrodes disposed within the electrostatic chuck. A seasoning layer is deposited on the support surface, including over the plurality of mesas, and is doped with carbon.

In another embodiment, a processing chamber includes a chamber body having a processing volume defined within and an electrostatic chuck disposed within the processing volume. The electrostatic chuck comprises a material having a resistivity between about 1E+6 ohm-cm. and about 1E+10 ohm-cm.

In yet another embodiment, a method of forming a seasoning layer on an electrostatic chuck is disclosed. The method includes heating the processing volume to a temperature above 500 degrees Celsius, introducing one or more precursor gases into the processing volume for a time interval, energizing a plasma within the processing volume with the one or more precursor gases, depositing the seasoning layer on the electrostatic chuck by a chemical vapor deposition process utilizing the plasma, and doping the seasoning layer with carbon using a carbon-containing precursor gas to tune a dielectric constant of the seasoning layer between 3 and 12.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of scope, and may admit to other equally effective embodiments.

FIG. 1 illustrates a simplified front cross-sectional view of a processing chamber having an electrostatic chuck therein according to one embodiment of the present disclosure.

FIG. 2 illustrates a simplified front cross-sectional view of the processing chamber of FIG. 1 showing a substrate disposed on an electrostatic chuck during processing thereof according to one embodiment of the present disclosure.

FIG. 3 illustrates an enlarged front cross-sectional view of the electrostatic chuck of FIG. 1 according to one embodiment of the present disclosure.

FIG. 4 illustrates a block diagram of a method of forming a seasoning layer on an electrostatic chuck according to one embodiment of the present disclosure.

To facilitate understanding, identical reference numerals have been used, where possible, to designate identical elements that are common to the figures. It is contemplated that elements and features disclosed in one embodiment may be beneficially incorporated in other embodiments without specific recitation.

### DETAILED DESCRIPTION

Embodiments of the disclosure relate to an improved electrostatic chuck for use in a processing chamber to fabricate semiconductor devices. In one embodiment, a processing chamber includes a chamber body having a processing volume defined therein and an electrostatic chuck disposed within the processing volume. The electrostatic chuck includes a support surface with a plurality of mesas located thereon, one or more electrodes disposed within the electrostatic chuck, and a seasoning layer deposited on the support surface over the plurality of mesas. The support surface is made from an aluminum containing material. The one or more electrodes are configured to form electrostatic charges to electrostatically secure a substrate to the support surface. The seasoning layer is configured to provide cushioning support to the substrate when the substrate is electrostatically secured to the support surface.

In one embodiment, a seasoning layer is deposited on the support surface of the electrostatic chuck using one or more precursor gases. The seasoning layer inhibits current leakage from the electrostatic chuck when it is operated at high temperatures. By changing the amount of carbon-containing precursor gases in the processing chamber, the magnitude of carbon doped into in the seasoning layer can be modulated. Modulation of the carbon concentration in the seasoning layer cushions the substrate from damage resulting from direct contact and movement over a plurality of mesas on the electrostatic chuck, while trapping sufficient charges for chucking the substrate thereon. A method for preparing and doping the seasoning layer is also disclosed.

In another embodiment, the electrostatic chuck material is modified in either of two ways. The top surface of the electrostatic chuck contacting the substrate, including the top surface of each of the plurality of mesas, is polished to a surface roughness of less than 0.25 microns, and/or a significantly higher number of mesas is distributed on the top surface of the electrostatic chuck. This enables an increase in the contacting surface area of the substrate with the electrostatic chuck, and thus reduces the contact force at each region of contact between the mesas and the substrate for the same chucking force. Alternatively, the electrostatic chuck comprises a material having a high volume resistivity between about 1E+6 ohm-cm and about 1E+10 ohm-cm and the contact surfaces with the substrate, including the top surfaces of each of the plurality of mesas, are seasoned with a layer of amorphous carbon. The high resistivity material prevents or substantially reduces current leakage such that the substrate can be secured to the electrostatic chuck with a reduced chucking voltage. A reduced chucking voltage reduces the contact force between the substrate and the plurality of mesas, such that damage to the backside of the substrate can be reduced or prevented. Additionally, the seasoning layer of amorphous carbon adds a cushioning effect to minimize or even eliminate any scratching damage to the mesa-contacting areas of the substrate,

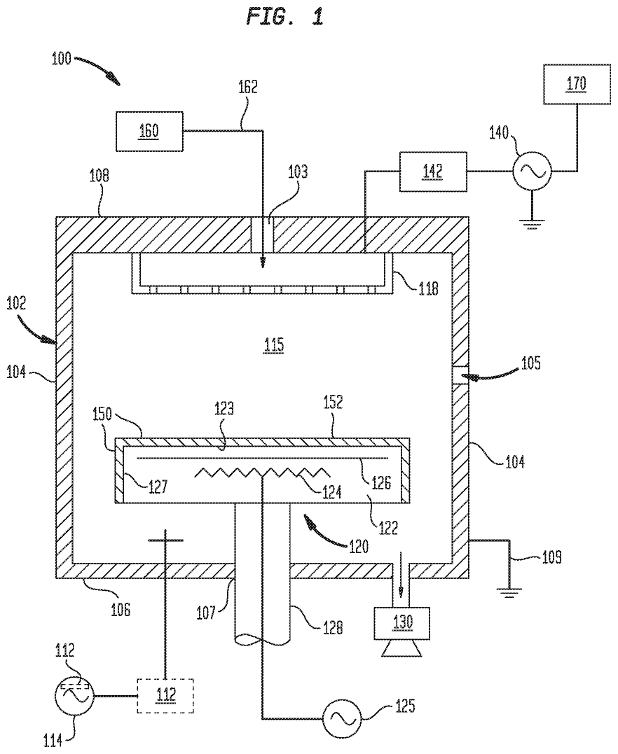

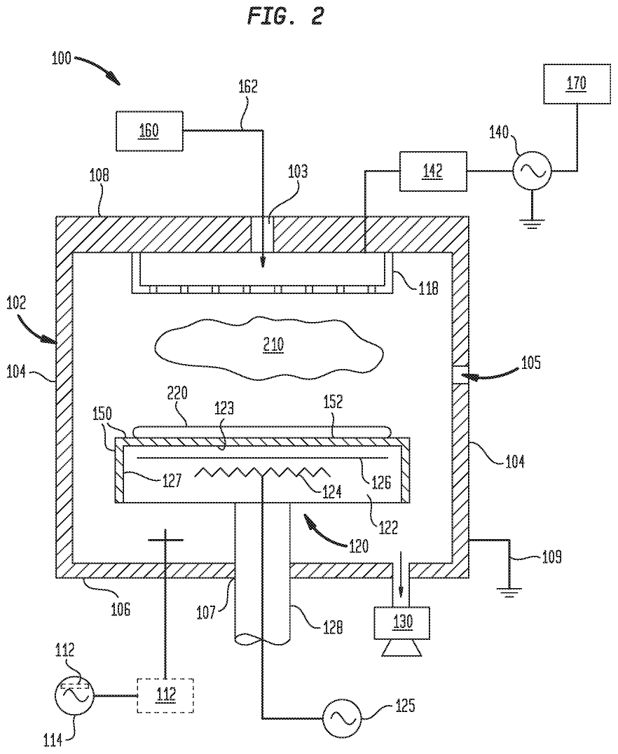

FIG. 1 illustrates a simplified front cross-sectional view of a processing chamber 100, having an electrostatic chuck 120 according to one embodiment of the disclosure. FIG. 2 illustrates a simplified front cross-sectional view of the chamber 100 of FIG. 1 depicting the substrate 220 disposed on the electrostatic chuck 120. The processing chamber 100 may be a chemical vapor deposition (CVD) chamber as shown, or other suitable plasma processing chamber. Examples of a processing chamber 100 that may be adapted to benefit from the disclosure include plasma-enhanced chemical vapor deposition (PECVD) chambers, such as but not limited to the CENTURA® apparatus, the PRODUCER® apparatus, the PRODUCER® GT apparatus, the PRODUCER® XP Precision™ apparatus, and the PRODUCER® SE™ apparatus which are available from Applied Materials, Inc., Santa Clara, Calif. It is contemplated that processing chambers from other manufacturers may also be adapted to benefit from the embodiments described herein. Although FIG. 1 described herein is illustrative of a PECVD chamber, the processing chamber 100 should not be construed or interpreted as limiting the scope of the embodiments described herein. The embodiments described herein can be equally applied to apparatus utilized for physical vapor deposition (PVD), etching, implanting, annealing, and plasma-treating materials on semiconductor substrates, among others.

As illustrated in FIG. 1, the processing chamber 100, shown schematically, includes a chamber body 102. The chamber body 102 has sidewalls 104, a bottom wall 106, and a chamber cover 108. The sidewalls 104, the bottom wall 106, and the cover 108 may be formed from conductive materials, such as aluminum, stainless steel, or alloys and combinations thereof. The sidewalls 104 and the bottom wall 106 are coupled to an electrical ground 109 when the processing chamber 100 is a plasma processing chamber. The chamber cover 108, the sidewalls 104, and the bottom wall 106 define a processing volume 115 therein. The sidewalls 104 include a substrate transfer port 105 to facilitate transfer of substrates 220 into and out of the processing volume 115. The substrate transfer port 105 may be coupled to a transfer chamber (not shown) and/or other chambers of a substrate processing system (not shown).

The dimensions of the chamber body 102 and related components of the processing chamber 100 are not limited and generally are proportionally larger than the size of the substrate 220 to be processed therein. The substrate 220 may be sized to have a diameter of 200 mm or less, 300 mm, and 450 mm or larger depending upon the desired implementation.

A gas panel 160 is fluidly connected by a conduit 162 to the processing volume 115 to provide one or more precursor gases or other process gases to the processing chamber 100. The conduit 162 is connected to an opening 103 through the chamber cover 108. A pump 130 is fluidly connected to the processing volume 115 to pump out the process gases and to maintain vacuum conditions within the processing volume 115 during substrate processing. The pump 130 may be a conventional roughing pump, roots blower, turbo pump, or other similar device that is adapted control the pressure in the processing volume 115 to a desired level.

A showerhead 118 is coupled to the chamber cover 108 and located above the electrostatic chuck 120 in the processing volume 115. The showerhead 118 is configured to introduce one or more precursor gases into the processing volume 115 of the processing chamber 100. The showerhead 118 also functions as an electrode for coupling RF power to the process gases introduced into the processing volume 115. The process gases from the gas panel 160 enter the processing volume 115 through the showerhead 118.

As illustrated in FIG. 2, an RF power source 140 is coupled to the showerhead 118 through an impedance matching circuit 142. The RF power source 140 is configured to provide the power necessary for striking and sustaining the plasma 210 formed from the gases within the processing volume 115. The operation of the RF power source 140 is controlled by a controller 170 that also controls the operation of other components in the processing chamber 100.

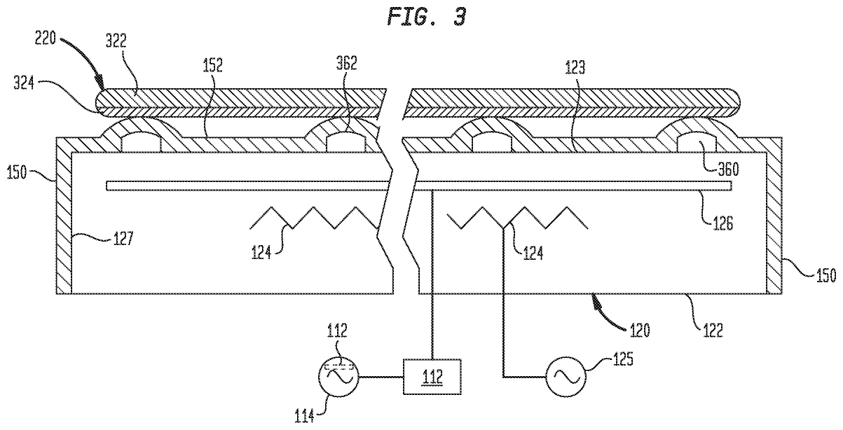

The electrostatic chuck 120 is disposed within the processing volume 115. The electrostatic chuck 120 is supported on a hollow stem 128 and includes a chuck body 122 coupled to the stem 128. The stem 128 is connected to an opening 107 through the bottom wall 106 sealed by, for example, a flexible bellows (not shown). The chuck body 122 electrostatically chucks the substrate 220 disposed thereon during processing of the substrate in the processing chamber 100. The chuck body 122 is formed from a dielectric material, for example a ceramic material, such as aluminum nitride (AlN) among other suitable materials. The electrostatic chuck 120 has a top surface 123 comprising a plurality of mesas (shown in FIG. 3) and a side surface 127.

The chuck body 122 includes a heater 124 embedded therein. The heater 124 is coupled to a power source 125. The heater 124 may be a resistive heating element, an inductive heating element, or other suitable heater. The heater 124 is configured to heat the electrostatic chuck 120 and the substrate 220 during processing to a temperature between about 100 degrees Celsius and about 700 degrees Celsius. The electrostatic chuck 120 may also be actively cooled, such as by flowing a coolant through cooling channels (not shown) therein. By actively balancing the heat input from the heater 124 and the cooling of the coolant, the temperature of the electrostatic chuck 120 and the substrate 220 placed thereon can be closely controlled.

A temperature sensor (not shown), such as but not limited to a thermocouple, may be connected to the chuck body 122 to measure the temperature of the electrostatic chuck 120. The temperature sensor is configured to communicate a signal indicative of the temperature of the chuck body 122 to a temperature controller (not shown) which provides a control signal to the power source 125 to change the power supplied to the heater, or change the flow rate, temperature, or both of the coolant, when the heat input or loss related thereto changes.

A chucking electrode 126 is embedded within the chuck body 122 of the electrostatic chuck 120. The chucking electrode 126 is connected to a power source 114 through an isolation transformer 112 disposed between the power source 114 and the chucking electrode 126. The isolation transformer 112 may be part of the power source 114, or be separate from the power source 114, as shown by the dashed lines in FIG. 1. The power source 114 is configured to apply a chucking voltage between about 50 V_{DC} and about 5000 V_{DC} to the chucking electrode 126 of the electrostatic chuck 120 to chuck the substrate 220. The power source 114 may communicate with a controller (not shown) configured to control the operation of the chucking electrode 126 by selecting the current value supplied to the chucking electrode 126 for chucking and de-chucking of the substrate 220.

In an embodiment, a seasoning layer 150 is deposited at least on the top surface 123 of the chuck body 122 before the substrate 220 is transferred into the processing chamber 100 through the substrate transfer port 105. In one embodiment, the seasoning layer 150 is a layer of silicon nitride, silicon carbon nitride, silicon oxycarbide, silicon oxide, or nitrogen-doped carbon having a thickness between about 100 nm and about 20 microns. The seasoning layer 150 is deposited using silicon containing precursors, carbon containing precursors, and/or nitrogen containing precursors. Examples of silicon containing precursors include silane (SiH₄), tetraethyl orthosilicate (TEES), di-methyl-silane (DMS), and tri-methyl-silane (TMS), among others. Examples of carbon containing precursors include propylene, acetylene, ethylene, methane, hexane, hexane, isoprene, and butadiene, among others. Examples of nitrogen containing precursors include pyridine, aliphatic amine, amines, nitriles, ammonia, among others. The seasoning layer 150 is uniformly deposited by a chemical vapor deposition process as discussed herein, or in a separate process when removed from the chamber, including by a spray process, a dipping process, a thermal process, or other suitable manner.

After the seasoning layer 150 is deposited over at least the top surface 123 of the electrostatic chuck 120 and optionally over the side surface 127 of the electrostatic chuck 120, a substrate 220 is transferred into the chamber 100 through the substrate transfer port 105 and placed on a top surface 152 of the seasoning layer 150. At temperatures above 500 degrees Celsius, charges are trapped at the interface between the seasoning layer 150 and the substrate 220. Charge trapping inhibits current leakage from the chucking electrode 126 to the substrate 220, and thus reduces the chucking voltage utilized to generate sufficient chucking force for chucking the substrate 220 to the electrostatic chuck 120.

The dielectric constant of the seasoning layer 150 can be tuned between about 3 and about 12 to enable controlled charge trapping and modification of the chucking force at temperatures greater than 500 degrees Celsius. The seasoning layer 150 may be doped with trace amounts of carbon using a carbon-containing precursor gas in the processing chamber 100 such that the resultant doped seasoning layer 150 has charge-leaking behavior yet low physical hardness. By modulating the content of carbon therein, the seasoning layer 150 can be fabricated to provide sufficient charge trapping and physically cushioned support to the substrate 220. As a result, when the substrate 220 is processed at high temperatures such as at or above 500 degrees Celsius, backside damage to the substrate 220, or particle generation, due to direct contact and movement over the top surface 123 of the electrostatic chuck 120 can be minimized or eliminated by the cushioning supplied by the seasoning layer 150. Thus, the deposition of the seasoning layer 150 enables the electrostatic chuck 120 to substantially flatten and sufficiently secure the substrate 220 thereon and reduce backside damage on the substrate 220, while enabling the application of a reduced chucking voltage.

The performance of the seasoning layer 150 can be evaluated based on the seasoning layer's refractive index, modulus/hardness, temperature-dependent leakage current, and chucking behavior. The refractive index provides information about the composition of the seasoning layer 150, the modulus/hardness provides information about the mechanical strength of the seasoning layer 150, the leakage current provides information about the charge-trapping effectiveness of the seasoning layer 150, and the chucking behavior provides information about how well the substrate 220 can be chucked by the electrostatic chuck 120 through the seasoning layer 150.

FIG. 3 illustrates an enlarged front cross-sectional view of the electrostatic chuck 120. The top surface 123 of the electrostatic chuck 120 has a plurality of mesas 360 extending from the top surface 123 of the electrostatic chuck 120. The substrate 220 is supported on a top surface 362 of the mesas 360. A seasoning layer 150 is deposited at least on the top surface 123 of the chuck body 122 including over the top surface 362 of the plurality of mesas 360 located thereon. The seasoning layer 150 extends over the top surface 123 including the top surface 362 of the mesas 360 and on the side surface 127 of the electrostatic chuck 120. In one embodiment, the substrate 220 is a single crystal silicon substrate. The substrate 220 has a first layer 322 disposed on the front surface of the substrate 220. The first layer 322 includes, but is not limited to, a multi-layer stack of oxide containing materials, nitride containing materials, or polysilicon containing materials. A second layer 324 is disposed on a backside of the substrate 220 which includes at least one of a silicon nitride containing material, a silicon oxide containing material, an amorphous silicon containing material, and polysilicon containing materials, etc.

The mesas 360 comprise square or rectangular blocks, cones, wedges, pyramids, posts, cylindrical mounds, or other protrusions of varying sizes, or combinations thereof extending from the top surface 123 of the electrostatic chuck 102. As the substrate 220 is electrostatically chucked by a chucking force applied by the chucking electrode 126, a contact force is generated at the contact region between each mesa 360 and the second layer 324 on the backside of the substrate 220. In one embodiment, the number of mesas 360 is between 100 and 200. In other embodiments, the number of mesas 360 are between 700 and 800, such that the number of contact regions with the substrate 220 is higher, thus reducing the contact force at each contact region between the mesas 360 and the substrate 220.

In alternate embodiments or in addition to the deposition of the seasoning layer 150, the top surface 362 of the mesas 360 on the electrostatic chuck 120 are highly polished to have a surface roughness of less than 0.25 microns. In the same or alternate embodiments, the number of mesas 360 may be increased from, for example, 100 to 800 such that the contact force at each contact region between the mesas 360 and the substrate 220 is reduced for the same chucking force. As a result, when the substrate 220 is heated from a relatively low substrate transfer temperature to a process temperature equal to or greater than 500 degrees Celsius, backside damage from direct contact and movement over the mesas 360 of the electrostatic chuck 120 can be minimized or eliminated.

Additionally, the polished top surface 362, having a surface roughness of less than 0.25 microns, reduces current leakage from the mesas 360 to the substrate 220. As the electrostatic attraction between the substrate 220 and electrostatic chuck 120 moves into the Johnsen-Rahbek regime at a temperature above 500 degrees Celsius, the charges are trapped at the interface between the substrate 220 and the electrostatic chuck 120. As a result, the chucking voltage utilized to generate sufficient chucking force to chuck the substrate 220 to the electrostatic chuck 120 is reduced.

In other embodiments, the electrostatic chuck 120 includes a material having a volume resistivity that is more than 10 times the resistivity of conventional materials used for the electrostatic chuck 120, for example, between about 1E+6 ohm-cm and about 1E+10 ohm-cm. The high resistivity material prevents current leakage such that the substrate 220 can be secured to the electrostatic chuck 120 with a lower chucking voltage. Further, a lower chucking voltage reduces the contact forces such that backside damage to the substrate 220 due to direct contact with and movement over the mesas 360 of the electrostatic chuck 120 can be reduced or prevented. In conjunction with the use of the high resistivity material, the top surface 123 of the electrostatic chuck 120 may be seasoned with a layer of amorphous carbon. Amorphous carbon has low hardness and, when utilized as a seasoning material over the top surface 123, acts as an effective cushion to protect the substrate 220 from damages due to abrasive scratches from the direct contact and movement over the mesas 360.

The processing chamber 100 incorporating the electrostatic chuck 120 described herein can be advantageously used to chuck substrates 220 having large warpage or bowing across a diameter thereof resulting from the stacks of oxide, nitride, and polysilicon layers disposed thereon. For example, the substrate 220 chucked to the electrostatic chuck 120 can be used to deposit a hardmask layer thereon for subsequent patterning and etching of the multi-layer stack, as well as any additional layers.

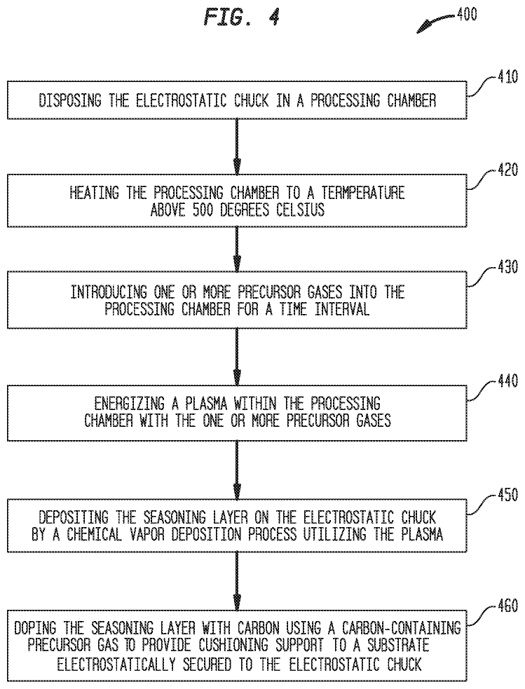

FIG. 4 illustrates a block diagram of a method 400 of forming the seasoning layer 150 on the electrostatic chuck 120 disposed within the processing chamber 100 described above. The method 400 begins at operation 410 by disposing an electrostatic chuck in a processing volume. The electrostatic chuck has aluminum-based top and side surfaces. There is no substrate on the electrostatic chuck so the seasoning layer can be deposited on the top surface and the side surface of the electrostatic chuck in situ. At operation 420, the processing volume is heated to a temperature above 500 degrees Celsius, A heating element disposed within the electrostatic chuck may be used to heat the electrostatic chuck at this time.

At operation 430, one or more precursor gases are introduced into the processing volume for a time interval. The one or more precursor gases may be silicon containing precursors, carbon containing precursors, and/or nitrogen containing precursors. Examples of silicon precursors include silane (SiH₄), tetraethyl orthosilicate (TEOS), di-methyl-silane (DMS), and tri-methyl-silane (TMS), among others. Examples of carbon containing precursors include propylene, acetylene, ethylene, methane, hexane, hexane, isoprene, and butadiene, among others. Examples of nitrogen containing precursors include pyridine, aliphatic amine, amines, nitriles, and ammonia, among others. In some embodiments, the precursor gases may be introduced simultaneously, while in other embodiments, the precursor gases are introduced sequentially. In some embodiments, the precursor gases are introduced for a time interval between about 1 second to about 3600 seconds. The precursor gases flow from a gas panel fluidly connected to the processing chamber via a showerhead.

At operation 440, a plasma is formed in the processing chamber by energizing the one or more precursor gases. An RF power source coupled to the processing chamber is used to generate the plasma within the processing volume of the chamber. At operation 450, a seasoning layer is deposited on the top surface and the side surface of the electrostatic chuck by chemical vapor deposition utilizing the plasma formed from the one or more precursor gases. The seasoning layer may be a layer of silicon nitride, silicon carbon nitride, silicon oxycarbide, silicon oxide, and nitrogen-doped carbon, among others, depending on the precursor gases used. The seasoning layer has a thickness between about 100 nm and about 20 microns.

At operation 460, the seasoning layer is doped with carbon, enabling the seasoning layer to provide cushioning support to a substrate disposed on the electrostatic chuck. The carbon is doped into the seasoning layer by introducing carbon-containing precursor gases containing free carbon radicals, such as but not limited to, TMS or any of the carbon precursors mentioned above. The amount of carbon doped into the seasoning layer is selected to minimize current leakage through the seasoning layer to the substrate 220 and maintain sufficient cushioning.

The processing chamber, as well as the methods described above, are advantageously utilized to minimize or eliminate abrasive backside scratching damage on a substrate resulting from direct contact and movement thereof over the mesas and rough surfaces of the electrostatic chuck during the processing thereof in the processing chamber. The scratching reduction is advantageous when a substrate at a relatively low substrate transfer temperature is located on a hot electrostatic chuck, particularly when a substrate having multiple layers of nitride and/or polysilicon is subject to a large chucking force applied by the electrostatic chuck. The substrates are observed to have a warp or bow from about (−) 400 um (i.e. under compressive stress) to (+) 400 um (i.e. under tensile stress) due to coefficient of thermal expansion mismatch between the layers of the stack at the time the substrates are transferred into the processing chamber. The seasoning layer described herein provides a cushioning support against damage to the substrate.

The cushioning effect is achieved by changing the amount of carbon-containing precursor gases in the chamber, thus modulating the content of carbon doped into the seasoning layer at different temperatures, such that a suitable level of charge trapping and cushioning effect is achieved. Seasoning of the electrostatic chuck enables the electrostatic chuck to apply a larger chucking force to substantially flatten the substrates during high temperature processing, with reduced damage to the chucked backside of the substrate. As a result, the subsequently deposited film layers on the substrate exhibit improved thickness uniformity and consistency in film properties, such as bevel coverage. The alternative embodiments—(i) an electrostatic chuck with a surface roughness less than 0.25 microns and/or more than 700 mesas disposed thereon and (ii) an electrostatic chuck fabricated from a high resistivity material and seasoned with amorphous carbon—are equally capable of achieving this advantageous effect.

Embodiments of the improved electrostatic chuck reduce power consumption during substrate processing. By trapping charges at the interface between a substrate and the electrostatic chuck when the substrate is processed at temperatures above 500 degrees Celsius, the electrostatic chuck reduces or eliminates current leakage. Thus, the voltage necessary to generate a sufficient chucking force on the substrate is reduced.

While the foregoing is directed to particular embodiments of the present disclosure, it is to be understood that these embodiments are merely illustrative of the principles and applications of the present disclosure. It is therefore to be understood that numerous modifications may be made to the illustrative embodiments to arrive at other embodiments without departing from the spirit and scope of the present disclosure, as defined by the appended claims.

1. A processing chamber apparatus, comprising:
a chamber body defining a processing volume therein; and
an electrostatic chuck disposed within the processing volume, the electrostatic chuck comprising:
a support surface made from an aluminum containing material, the support surface having a plurality of mesas disposed thereon;
one or more electrodes disposed within the electrostatic chuck; and
a seasoning layer deposited on the support surface and extending over the plurality of mesas, wherein the seasoning layer is doped with carbon.

2. The apparatus of claim 1, wherein the seasoning layer comprises:
one or more of a silicon nitride material, a silicon carbon nitride material, a silicon oxycarbide material, a silicon oxide material, and a nitrogen-doped carbon material.

3. The apparatus of claim 2, wherein a dielectric constant of the seasoning layer is between 3 and 12.

4. The apparatus of claim 1, wherein the seasoning layer has a thickness between 100 nm and 20 microns.

5. The apparatus of claim 1, wherein each of the plurality of mesas has a surface roughness of less than 0.25 microns.

6. An electrostatic chuck comprising:
a chuck body having an embedded chucking electrode, the chuck body comprising a material having a volume resistivity between 1E+6 ohm-cm and 1E+10 ohm-cm.

7. The electrostatic chuck of claim 6, further comprising:
a seasoning layer of amorphous carbon disposed on a support surface of the chuck body, the support surface having plurality of mesas.

8. The electrostatic chuck of claim 7, wherein the seasoning layer has a thickness of between 100 nanometers and 20 microns.

9-15. (canceled)

16. The electrostatic chuck of claim 7, wherein the seasoning layer is uniformly deposited on the support surface.

17. The electrostatic chuck of claim 7, wherein the seasoning layer is further deposited over a side surface of the chuck body.

18. The electrostatic chuck of claim 7, wherein the seasoning layer has a dielectric constant between about 3 and about 12.

19. An electrostatic chuck comprising:
a chuck body having a support surface made from an aluminum containing material, the support surface having a plurality of mesas disposed thereon;
one or more chucking electrodes disposed within the chuck body; and
a seasoning layer disposed on the support surface and extending over the plurality of mesas, wherein the seasoning layer is doped with carbon.

20. The electrostatic chuck of claim 19, wherein the seasoning layer comprises amorphous carbon.

21. The electrostatic chuck of claim 19, wherein the seasoning layer comprises:
one or more of a silicon nitride material, a silicon carbon nitride material, a silicon oxycarbide material, a silicon oxide material, and a nitrogen-doped carbon material.

22. The electrostatic chuck of claim 19, wherein the seasoning layer has a thickness of between about 100 nanometers and about 20 microns.

23. The electrostatic chuck of claim 19, wherein the seasoning layer is uniformly deposited on the support surface.

24. The electrostatic chuck of claim 19, wherein the seasoning layer is further deposited over a side surface of the chuck body.

25. The electrostatic chuck of claim 19, wherein the seasoning layer has a dielectric constant between about 3 and about 12.

26. The electrostatic chuck of claim 19, further comprising a material having a volume resistivity between 1E+6 ohm-cm and 1E+10 ohm-cm.

27. The electrostatic chuck of claim 19, wherein each of the plurality of mesas has a surface roughness of less than 0.25 microns.
